(19) United States
(12) Patent Application Publication
(10) Pub. No.: US 2006/0186491 A1
(43) Pub. Date: Aug. 24, 2006

(54) Methods of forming semiconductor devices having metal gate electrodes and related devices

(76) Inventors: Hee-Sook Park, Seoul (KR); Sun-Pil Youn, Seoul (KR); Chang-Won Lee, Gyeonggi-do (KR)

Correspondence Address: MYERS BIGEL SIBLEY & SAJOVEC, PO BOX 37428, RALEIGH, NC, 27627, US

(21) Appl. No.: 11/384,789

(22) Filed: Mar. 20, 2006

Related U.S. Application Data
(63) Continuation-in-part of application No. 10/780,244, filed on Feb. 17, 2004.

(30) Foreign Application Priority Data
Feb. 19, 2003 (KR) 10-2003-0010403
Feb. 22, 2006 (KR) 2006-17267

(51) Int. Cl. H01L 29/94; H01L 21/3205

(52) U.S. Cl. 257/412; 257/413; 438/585; 257/E29.127

(57) ABSTRACT

Methods of forming semiconductor devices and the devices so formed include forming an oxidation barrier pattern to cover sidewalls of a metal-containing pattern. The metal-containing pattern is located on a gate polysilicon layer and includes a metal silicide pattern, a metal barrier pattern and a gate metal pattern which are sequentially stacked. An oxide layer is not formed between the metal barrier pattern and the gate polysilicon pattern. Furthermore, a metal silicide pattern located between the metal barrier pattern and the gate polysilicon pattern functions not only as an ohmic layer decreasing a contact resistance between the metal barrier pattern and the gate polysilicon pattern but also as an oxidation barrier to prevent a metal such as tungsten from being oxidized. Therefore, semiconductor devices have improved operational speed and/or reliability.

### RELATED APPLICATIONS

This application claims priority to Korean Patent Application Serial No. 10-2006-0017267, filed Feb. 22, 2006, and is a continuation-in-part of U.S. patent application Ser. No. 10/780,244, filed Feb. 17, 2004, which claims priority to Korean Patent Application No. 10-2003-0010403, filed Feb. 19, 2003, the contents of which are hereby incorporated by reference as if recited in full herein.

### FIELD OF THE INVENTION

The present invention relates to methods of forming semiconductor devices and the devices so formed. More particularly, the present invention relates to a method of forming semiconductor devices having at least one metal gate electrode and the devices so formed.

### BACKGROUND OF THE INVENTION

As semiconductor devices become more highly integrated, the size of gate electrodes can be reduced, which, in turn, can increase electrical resistance of a gate electrode and decrease operational speed of a semiconductor device. In order to decrease electrical resistance of gate electrodes for increasing operation speed, a metal layer, such as tungsten, is typically introduced as a component for a gate electrode.

FIG. 1 is a cross-sectional diagram of a conventional semiconductor device. Referring to FIG. 1, a gate insulation layer 3, a gate polysilicon layer 5, a barrier metal layer 7, a gate metal layer 9, and a capping layer 11 are sequentially formed and patterned to form a gate pattern 13. In order to cure etch damage that can be caused at the semiconductor substrate 1 and/or the gate polysilicon layer 5 during the patterning process, a thermal process can be performed under an oxygen-enriched environment. At this time, an oxide layer O may be formed between the barrier metal layer 7 and the gate polysilicon layer 5. Oxygen diffuse through a side surface(s) of the gate metal layer 9 during thermal treatment in the oxygen-enriched environment, thereby forming the oxide layer O. The oxide layer O increases resistance between the gate metal layer 9 and the gate polysilicon layer 5. The increased resistance can result in one or more of a delay in the RC (time constant), a slower operational speed and/or decreased reliability in a semiconductor device.

Furthermore, although no oxide layer O is formed in the gate pattern of FIG. 1, a contact resistance between the barrier metal layer 7 and the gate polysilicon layer 5 may be unduly large and inhibit desired operational speed in integrated semiconductor devices.

### SUMMARY OF THE INVENTION

Embodiments of the invention provide methods of forming semiconductor devices that can improve operational speed and/or reliability.

According to some methods of forming a semiconductor device of the present invention, an oxidation barrier pattern is formed to cover sidewalls of the metal-containing pattern, and the metal-containing pattern located on a gate polysilicon layer includes a metal silicide pattern, metal barrier pattern and a gate metal pattern, which are sequentially stacked. The methods may be carried out so that an oxide layer (O, in FIG. 1) is inhibited (typically prevented) from forming between the metal barrier pattern and the gate polysilicon pattern.

In some embodiments, a metal silicide pattern located between the metal barrier pattern and the gate polysilicon pattern can function both as: (a) an ohmic layer that decreases a contact resistance between the metal barrier pattern and the gate polysilicon pattern; and (b) an oxidation barrier to inhibit (typically prevent) a metal, such as tungsten, from being oxidized. The resulting devices formed using the methods can have improved operational speed and with increased reliability over conventional devices.

In particular embodiments, the method of forming a semiconductor substrate includes sequentially forming a gate insulation layer, a gate polysilicon layer and a plurality of metal-containing layers on a semiconductor substrate; patterning the metal-containing layers to form a metal-containing pattern; and forming an oxidation barrier pattern covering sidewalls of the metal-containing pattern. The metal-containing layers can be formed by sequentially stacking a metal silicide layer, a barrier metal layer and a gate metal layer. The metal-containing pattern includes a metal silicide pattern, a barrier metal pattern and a gate metal pattern, which are sequentially stacked.

The forming of a metal-containing pattern may include forming a capping pattern on the metal-containing layer and patterning the metal-containing layer using the capping pattern as an etch mask.

According to some embodiments of the present invention, the forming of a metal-containing pattern may include etching the gate polysilicon layer using the capping pattern as an etch mask to form a gate polysilicon pattern having sidewalls aligned with sidewalls of the metal-containing pattern. The oxidation barrier pattern may be formed to cover only the sidewalls of the metal-containing pattern.

The forming of an oxidation barrier pattern may include selectively forming an oxidation barrier pattern covering only the sidewalls of the metal-containing pattern by performing a chemical vapor deposition or an atomic layer deposition.

The oxidation barrier pattern may comprise boron nitride, a metal, an oxide of the metal, a nitride of the metal or an oxynitride. The metal can comprise at least one selected from the group consisting of aluminum, tantalum, titanium, hafnium, molybdenum, cobalt and gold. The forming of an oxidation barrier pattern may include selectively forming a metal pattern covering the sidewalls of the metal-containing pattern by a chemical vapor deposition or an atomic layer deposition, and oxidizing or nitrifying or successively oxidizing and nitrifying the metal pattern.

The oxidation barrier pattern may comprise aluminum oxide (Al₂O₃), and the forming of the oxidation barrier pattern may include forming an aluminum pattern covering substantially only the sidewalls of the metal-containing pattern by using a chemical vapor deposition and by supplying a gas mixture, which may comprise a source gas such as methylpyrrolidine alane (MPA) and a second gas as a carrier gas. The carrier gas can comprise argon (Ar). The source and carrier gases can be provided at a temperature of between about 135˜145° C. and at a pressure of between about 0.1˜1.1 Torr. The carrier gas, such as argon, can be provided at a flow rate of about 100 sccm. The aluminum layer can be oxidized under an oxygen-enriched environment.

According to another embodiment of the present invention, the oxidation barrier pattern may be formed to cover substantially only the sidewalls of the metal-containing pattern. The method may further include etching the gate polysilicon layer using the capping pattern and the oxidation barrier pattern as etch masks to form a gate polysilicon pattern having sidewalls aligned with sidewalls of the oxidation barrier pattern, after forming the oxidation barrier pattern.

According to still other embodiments of the present invention, the oxidation barrier pattern may be extended to cover sidewalls of the capping pattern, and the method may further include etching the gate polysilicon layer using the capping pattern and the oxidation barrier pattern as etch masks to form a gate polysilicon pattern having sidewalls aligned with sidewalls of the oxidation barrier pattern after forming the oxidation barrier pattern. The forming of an oxidation barrier pattern may include: (a) conformally forming an oxidation barrier layer over the semiconductor substrate having the metal-containing pattern; and (b) entirely anisotropically etching the oxidation barrier layer, thereby removing the oxidation barrier layer on the capping pattern and the gate polysilicon layer and simultaneously forming an oxidation barrier pattern covering the sidewalls of the metal-containing pattern and sidewalls of the capping pattern. The forming of an oxidation barrier layer may include selectively forming a metal layer over the semiconductor substrate having the metal-containing pattern; and oxidizing or nitrifying or successively oxidizing and nitrifying the metal layer.

The oxidation barrier layer may comprise aluminum oxide (Al₂O₃), and the forming of the oxidation barrier layer may be performed by using a chemical vapor deposition and by supplying a gas mixture comprising vapor of tri-methyl-aluminum (TMA) and ozone (O₃) as source gases and argon (Ar) as a carrier gas. The source and carrier gases may be provided at a temperature of between about 200˜600° C. and at a pressure of between about 0.1˜10 Torr.

According to still another embodiment of the present invention, the oxidation barrier layer may include a first oxidation barrier pattern covering substantially only sidewalls of the metal-containing pattern and a second oxidation barrier pattern covering sidewalls of the first oxidation barrier pattern and the capping pattern. The method may further include etching the gate polysilicon layer using the capping pattern and the second oxidation barrier pattern as etch masks to form a gate polysilicon pattern having sidewalls aligned with sidewalls of the second oxidation barrier pattern, after forming the oxidation barrier pattern. The forming of an oxidation barrier pattern may include: (a) selectively forming a first oxidation barrier pattern covering substantially only the sidewalls of the metal-containing pattern using a chemical vapor deposition or an atomic layer deposition method; (b) conformally forming an oxidation barrier layer over the semiconductor substrate having the first oxidation barrier pattern; and (c) performing an anisotropic etch process with respect to the oxidation barrier layer to remove the oxidation barrier layer on the capping pattern and the gate polysilicon layer and simultaneously to form a second oxidation barrier pattern covering sidewalls of the first oxidation barrier pattern and the capping pattern.

The first and second oxidation barrier patterns may comprise boron nitride, a metal, an oxide of the metal, a nitride of the metal or an oxynitride. The metal can be at least one selected from the group consisting of aluminum, tantalum, titanium, hafnium, molybdenum, cobalt and gold. Alternatively, the second oxidation barrier pattern may comprise silicon nitride.

The forming of a first oxidation barrier may include selectively forming a metal pattern covering substantially only sidewalls of the metal-containing pattern by using a chemical vapor deposition or an atomic layer deposition; and oxidizing or nitrifying or successively oxidizing and nitrifying the metal pattern.

The method may further include performing a thermal treatment process with respect to the semiconductor substrate having the oxidation barrier pattern and the gate polysilicon pattern under an oxygen-enriched environment. The thermal treatment process can be performed by supplying a gas mixture comprising nitrogen gas as a carrier gas, oxygen and hydrogen. The gas mixture may be provided at a temperature of between about 750˜950° C. and with a ratio of oxygen/hydrogen of between about 0.5˜1.3.

Other embodiments are directed to (highly integrated) semiconductor devices having a gate insulation pattern on a semiconductor substrate; a gate polysilicon pattern on the gate insulation pattern; a metal-containing pattern on the gate polysilicon pattern; a capping pattern on the metal-containing pattern; and an oxidation barrier pattern covering sidewalls of the metal-containing pattern. The metal-containing pattern comprises a metal silicide pattern, a metal barrier pattern and a gate metal pattern, which are serially (sequentially) stacked.

The gate polysilicon pattern may have sidewalls aligned with sidewalls of the metal-containing pattern, and the oxidation barrier pattern covers substantially only the sidewalls of the metal-containing pattern.

The gate polysilicon pattern may have sidewalls aligned with sidewalls of the oxidation barrier pattern.

The oxidation barrier pattern may cover substantially only the sidewalls of the metal-containing pattern. Alternatively, the oxidation barrier pattern may cover sidewalls of the capping pattern.

The oxidation barrier pattern may include a first oxidation barrier pattern covering substantially only sidewalls of the metal-containing pattern and a second oxidation barrier pattern covering sidewalls of the first oxidation barrier pattern and the capping pattern.

Some embodiments are directed to highly integrated semiconductor devices. The devices include a semiconductor substrate and a plurality of spaced apart gate structures disposed on the semiconductor substrate. Each gate structure includes, in serial order: (a) a polysilicon gate pattern; (b) a multi-layer metal-containing stacked pattern residing on the polysilicon gate pattern, the multi-layer metal-containing stacked pattern including a first metal silicide pattern residing on the polysilicon gate pattern, a second metal barrier pattern residing above the polysilicon gate pattern on the first metal silicide pattern, and a third gate metal pattern residing on the second metal barrier pattern above the first metal silicide pattern; c) a capping pattern residing on the third gate metal pattern of the multi-layer metal-containing pattern; and (d) at least one oxygen barrier pattern covering sidewalls of the metal-containing pattern, whereby after exposure to an oxygen enriched environment, the gate structures are devoid of an oxide layer intermediate the metal barrier pattern and the gate polysilicone pattern.

Still other embodiments are directed to methods of forming a highly integrated semiconductor device. The methods include sequentially forming a gate insulation layer, a gate polysilicon layer and a plurality of metal-containing layers on a semiconductor substrate. The metal-containing layers are formed by sequentially forming a first metal-containing layer on the gate polysilicon layer, then forming a second metal-containing barrier layer on the first metal-containing layer, then forming a third metal-containing gate layer on the second metal-containing barrier layer. At least one of the metal-containing layers has a different material composition from the others. The method also includes patterning the metal-containing layers to form a stacked metal-containing pattern; then forming an oxidation barrier pattern covering sidewalls of the metal-containing pattern.

The foregoing and other objects and aspects of the present invention are described in greater detail in the drawings herein and the specification set forth below.

### BRIEF DESCRIPTION OF THE DRAWINGS

FIG. 1 is a cross-sectional diagram of a prior art semiconductor device according to a conventional technology.

FIGS. 2 through 5 are cross-sectional diagrams of semiconductor devices illustrating an exemplary sequence of operations and/or configurations for forming semiconductor devices according to embodiments of the present invention.

FIGS. 6 through 9 are cross-sectional diagrams of semiconductor devices illustrating an alternative sequence of operations and/or configurations for forming semiconductor devices according to other embodiments of the present invention.

FIGS. 10 through 14 are cross-sectional diagrams of semiconductor devices illustrating yet another alternative sequence of operations and/or configurations for forming semiconductor devices according to still other embodiments of the present invention.

FIGS. 15 through 19 are cross-sectional diagrams of semiconductor devices illustrating still another alternative sequence of operations and/or configurations for forming semiconductor devices according to still other embodiments of the present invention.

### DESCRIPTION OF EMBODIMENTS OF THE INVENTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

In the figures, the thickness of certain lines, layers, components, elements or features may be exaggerated for clarity. Broken lines illustrate optional features or operations unless specified otherwise.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second without departing from the teachings of the present invention. Like numbers refer to like elements throughout. In addition, although described herein with respect to semiconductor substrates and devices, the present invention is directed to integrated circuits and can include structures formed on other substrates.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

The statements characterizing one or more of the priority applications as a “continuation-in-part” application of a prior application listed under the “Related Applications” section above is used to indicate that additional subject matter was added to the specification of the prior application but does not necessarily mean that the entire invention described and claimed in the present application is not supported in full by the prior application(s).

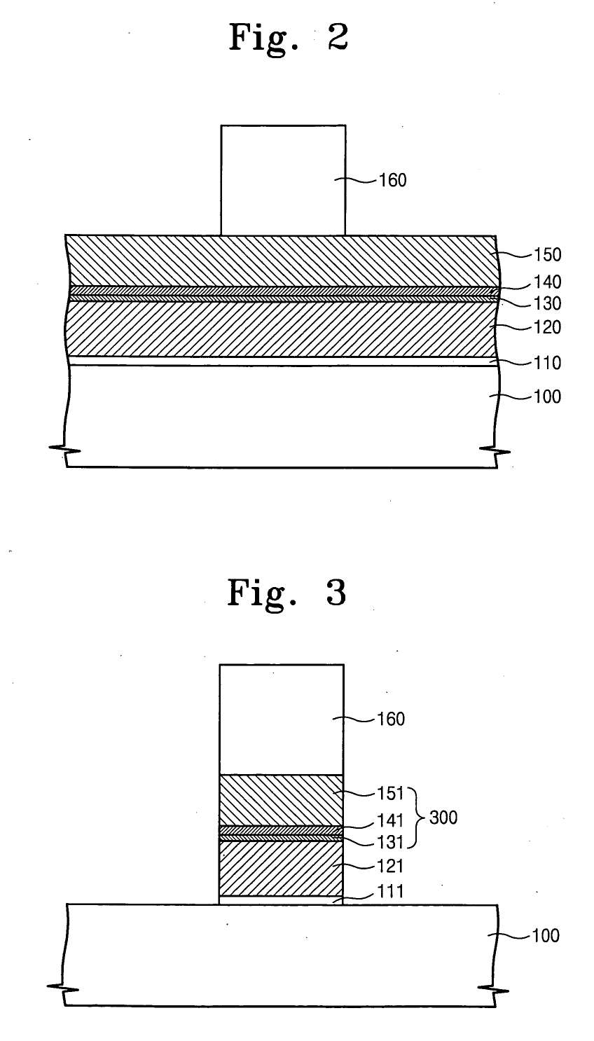

FIGS. 2 through 5 illustrate cross-sectional views of operations/semiconductor structures that can be used to form semiconductor devices according to embodiments of the present invention.

Referring to FIG. 2, a gate insulation layer 110 is formed on a semiconductor substrate 100. The gate insulation layer 110 may comprise silicon oxide formed by a thermal oxidation process. Alternatively, the gate insulation layer 110 may be a high-k oxide formed by a deposition process. For example, the gate insulation layer 110 may comprise at least one oxide selected from the group consisting of aluminum oxide, hafnium oxide and zirconium oxide. A gate polysilicon layer 120, a metal silicide layer 130, a barrier metal layer 140 and a gate metal layer 150 can be serially and/or sequentially formed on the gate insulation layer 110. The gate polysilicon layer 120 may be a polysilicon layer that may or may not be doped with impurities. The metal silicide layer 130 may comprise a silicide of various metals such as, for example, tungsten silicide, titanium silicide, cobalt silicide and so forth. The metal silicide layer 130 can be generated using a suitable deposition method such as chemical vapor deposition (CVD), atomic layer deposition (ALD) and/or a physical vapor deposition (PVD). The barrier metal layer 140 may comprise tungsten nitride or titanium nitride. The barrier metal layer 140 can be formed by using one or more of CVD, ALD or PVD. The gate metal layer 150 maybe formed of one or more metals, such as, for example, tungsten, aluminum and/or copper. The gate metal layer 150 can be formed by one or more of CVD, PVD or ALD.

A capping pattern 160 is formed on the gate metal layer 150. In order to form the capping pattern 160, a capping layer (not shown) is stacked on the gate metal layer 150. A photoresist pattern can be formed on the capping layer by a photolithography process. The capping layer can be etched by using the photoresist pattern as an etch mask to form the capping pattern 160. The capping pattern 160 may be formed of one or more of, for example, silicon nitride, silicon oxide or silicon oxynitride.

Referring to FIG. 3, the gate metal layer 150, the barrier metal layer 140, the metal silicide layer 130 and the gate polysilicon layer 120 are sequentially etched by using the capping pattern 160 as an etch mask. The gate insulation layer 110 may also be etched. The etch process forms a gate insulation pattern 111, a gate polysilicon pattern 121, a metal silicide pattern 131, a barrier metal pattern 141 and a gate metal pattern 151 which are sequentially stacked and have sidewalls aligned with each other. The outer perimeters of the respective sidewalls may be aligned so that they are collinear, typically residing in a substantially straight line. The metal silicide pattern 131, the barrier metal pattern 141 and the gate metal pattern 151 define a metal-containing pattern 300.

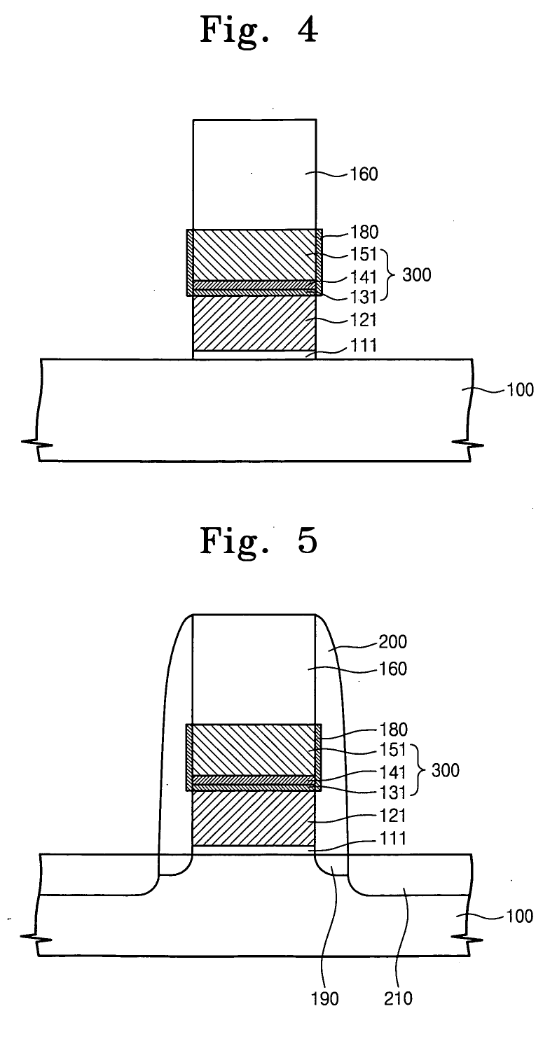

Referring to FIG. 4, an oxidation barrier pattern 180 is selectively formed to cover substantially only sidewalls of the metal-containing pattern 300. Thus, as shown, the oxidation barrier pattern 180 is substantially coextensive with the sidewalls of the metal-containing pattern and terminates at the upper boundary at the capping pattern 160, and at the lower boundary, at the gate polysilicon pattern 121. The oxidation barrier pattern 180 can be formed of a CVD and/or an ALD without requiring any etch process. Controlling a process condition of the CVD or the ALD allows the oxidation barrier pattern 180 to be selectively formed on the sidewalls of the metal-containing pattern 300. That is, by using a difference of a chemical property, such as, for example, a nucleation ration in the CVD or the ALD, the oxidation barrier pattern 180 can be very well deposited on the sidewalls of the metal-containing pattern 300 while being nominally (if at all) deposited on the non-meal containing pattern layers such as, for example, layers 100, 111, 121, and 160. The oxidation barrier pattern 180 may comprise boron nitride, a metal, an oxide of the metal, a nitride of the metal or an oxynitride of the metal. The metal may comprise at least one selected from the group consisting of aluminum, tantalum, titanium hafnium, molybdenum, cobalt and gold.

Alternatively, in order to form the oxidation barrier pattern 180, a metal pattern may be selectively deposited without a patterning process, then, oxidized or nitrified or successively oxidized and nitrified. The oxidation barrier pattern 180 may be formed to have a thickness of between about 5˜100 Å.

In certain embodiments, such as when the oxidation barrier pattern 180 is formed of aluminum oxide (Al₂O₃), an aluminum pattern may be formed substantially only on sidewalls of the metal-containing pattern 300 by supplying a gas mixture comprising methylpyrrolidine alane (MPA) as a source gas and argon (Ar) as a carrier gas. The Ar gas can be supplied at a flow rate of about 100 sccm. The gas mixture can be supplied at a temperature of between about 135˜145° C. and at a pressure of between about 0.1˜1.1 Torr. The gas mixture may be supplied for a suitable duration, such as, for example, about 5 seconds using a CVD method. The aluminum pattern can be naturally oxidized (at pressures at about and/or under atmospheric pressure) to form the aluminum oxide of the oxidation barrier pattern 180. The aluminum pattern may be selectively deposited on surfaces of the metal-containing pattern 300 with adjacent patterns 100, 111, 121 and 160 being substantially devoid of the aluminum pattern.

Referring to FIG. 5, a thermal treatment process can be performed with respect to the semiconductor substrate 100 having the gate pattern and the oxidation barrier pattern 180 under an oxygen-enriched environment to cure etch damage generated during the etch process (such as the etch process described above with respect to the pattern generated in FIG. 3). The thermal treatment process under the oxygen-enriched environment or ambience may be performed by supplying a gas mixture comprising, for example, nitrogen as a carrier gas and including hydrogen and oxygen. The gas mixture may be provided at a temperature of between about 750˜950° C. In particular embodiments, the ratio of oxygen/hydrogen may be between about 0.5˜1.3. The oxidation barrier layer 180, the metal silicide pattern 131 and the capping pattern 160 can inhibit oxygen penetration into the gate metal pattern 151. Therefore, no oxide layer is formed between the gate metal pattern 151 and the gate polysilicon pattern 121. Consequently, there is neither increase in resistance nor degradation in reliability of semiconductor devices.

A low-concentration impurity-doped region 190 can be formed in the semiconductor substrate 100 at both sides of the gate polysilicon pattern 121 by using the capping pattern 160 as an ion-implantation mask. The low-concentration impurity-doped region 190 may be formed before forming the oxidation barrier pattern 180. A spacer layer (not shown) can be conformally stacked over an entire surface of the semiconductor substrate 100 having the low-concentration impurity-doped region 190 and entirely anisotropically etched to form a spacer 200 covering the capping pattern 160, the metal-containing pattern 300, and the gas polysilicon pattern 121. The spacer 200 may comprise, for example, silicon oxide, silicon oxynitride and/or silicon nitride. Impurities are doped in the semiconductor substrate 100 by using the capping pattern 160 and the spacer 200 as ion-implantation masks to form a high-concentration impurity-doped region 210.

Referring to FIG. 5, in serial order, the gate insulation pattern 111, the gate polysilicon pattern 121, the metal silicide pattern 131, the barrier metal pattern 141, the gate metal pattern 151 and the capping pattern 160 are stacked to define a gate pattern. The gate polysilicon pattern 121, the metal silicide pattern 131, the barrier metal pattern 141, the gate metal pattern 151 and the capping pattern 160 have sidewalls that are substantially aligned with each other. The metal-containing pattern 300 that includes the metal silicide pattern 131, the barrier metal pattern 141 and the gate metal pattern 151 has sidewalls covered by the oxidation barrier pattern 180. The metal silicide pattern 131 functions not only as oxygen barrier but also an ohmic layer lowering a contact resistance between the barrier metal pattern 141 and the gate polysilicon pattern 121. The metal silicide pattern 131 can reduce resistance of a gate pattern and allow a semiconductor device to have increased operational speed.

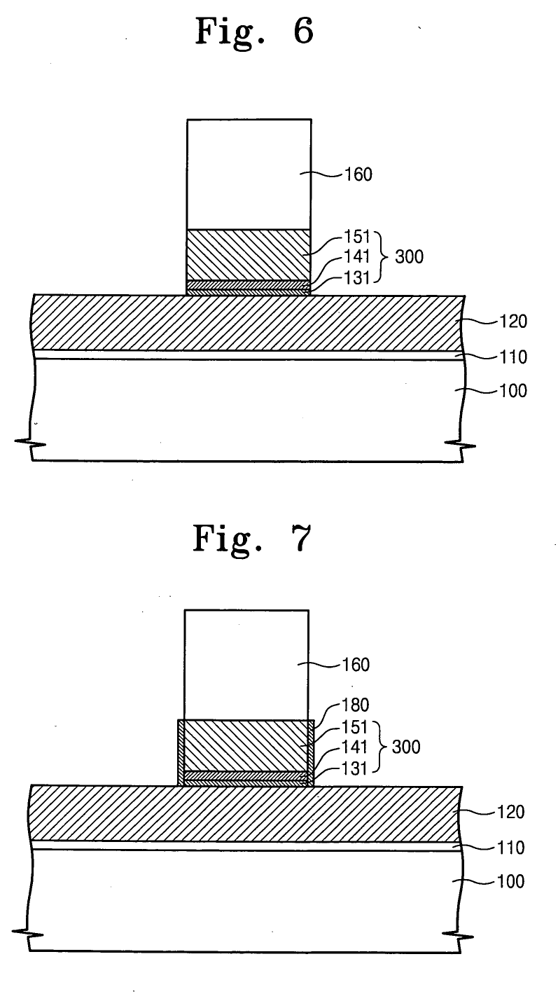

FIGS. 6 through 9 illustrate operations of another method of forming semiconductor devices according to embodiments of the present invention. FIG. 6 is similar to FIG. 3, but the gate polysilicon layer 120 is not etched and, hence, not exposed. Thus, with the same starting structure as shown in FIG. 2, after forming a capping pattern 160 on a gate metal layer 150 (FIG. 2), a gate metal layer 150, a barrier metal layer 140 and a metal silicide layer 130 are etched using the capping pattern 160 as an etch mask, but the gate polysilicon layer 120 is not etched to be exposed. As shown in FIG. 6, this etch process forms a metal-containing pattern 300 having a metal silicide pattern 131, a barrier metal pattern 141 and a gate metal pattern 151, which are sequentially stacked.

Referring to FIG. 7, an oxygen barrier pattern 180 is selectively formed on the sidewalls of the metal-containing pattern 300 using a deposition process such as a CVD or an ALD without any patterning process. This portion of the process is further described above with respect to FIG. 4.

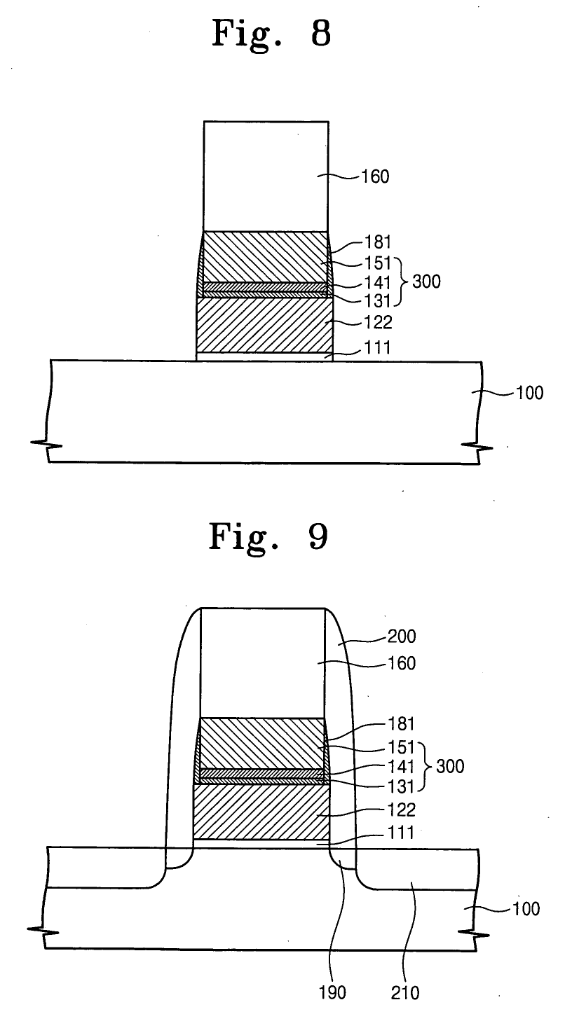

Referring to FIG. 8, the gate polysilicon layer 120 (FIG. 7) is etched using the capping pattern 160 and the oxidation barrier pattern 180 (FIG. 7) as etch masks. The gate insulation layer 110 may also be etched. As shown in FIG. 8, this results in forming a gate insulation pattern 111 and a gate polysilicon pattern 122. During the etch process, a top portion of the oxidation barrier pattern 180 can be partially etched to form an oxidation barrier pattern 181 whose top portion is thinner than its bottom portion. After the etch process, the sidewalls of the metal-containing pattern 300 are not exposed as they are covered by the oxidation barrier pattern 181. As shown, the gate polysilicon pattern 122 has both a width that is larger than a width of the metal-containing pattern 300 and sidewalls that are aligned with the sidewalls of the oxidation pattern 181. Stated differently, the outer perimeter profile of the gate polysilicon pattern 122 merges into and is substantially collinear with the lowermost portion of the outer perimeter profile (sidewalls) of the oxidation barrier pattern 181.

Referring to FIG. 9, a thermal treatment process can be performed under an oxygen-enriched environment to cure etch damage of the gate insulation pattern 111 and sidewalls of the gate polysilicon pattern 122. Impurities can be implanted into the semiconductor substrate 100 using the capping pattern 160 and the oxidation barrier pattern 181 as ion-implantation masks to form a low-concentration impurity-doped region 190. A spacer 200 is formed to cover sidewalls of the capping pattern 160, the oxidation barrier pattern 181 and the gate polysilicon pattern 122. Impurities can be implanted into the semiconductor substrate 100 using the capping pattern 160 and the spacer 200 as ion-implantation masks to form a high-concentration impurity-doped region 210. In this embodiment, the layers and process conditions can be the same as those explained above with reference to FIGS. 2 through 5.

Referring to FIG. 9, the gate insulation pattern 111, the gate polysilicon pattern 122, a metal silicide pattern 131, a barrier metal pattern 141, a gate metal pattern 151 and a capping pattern 160 are sequentially stacked to define a gate pattern. The metal-containing pattern 300 includes the metal silicide pattern 131, the barrier metal pattern 141 and the gate metal pattern 151 and has sidewalls that are covered by the oxidation barrier pattern 181. The gate polysilicon pattern 122 is wider than a width of the metal-containing pattern 300.

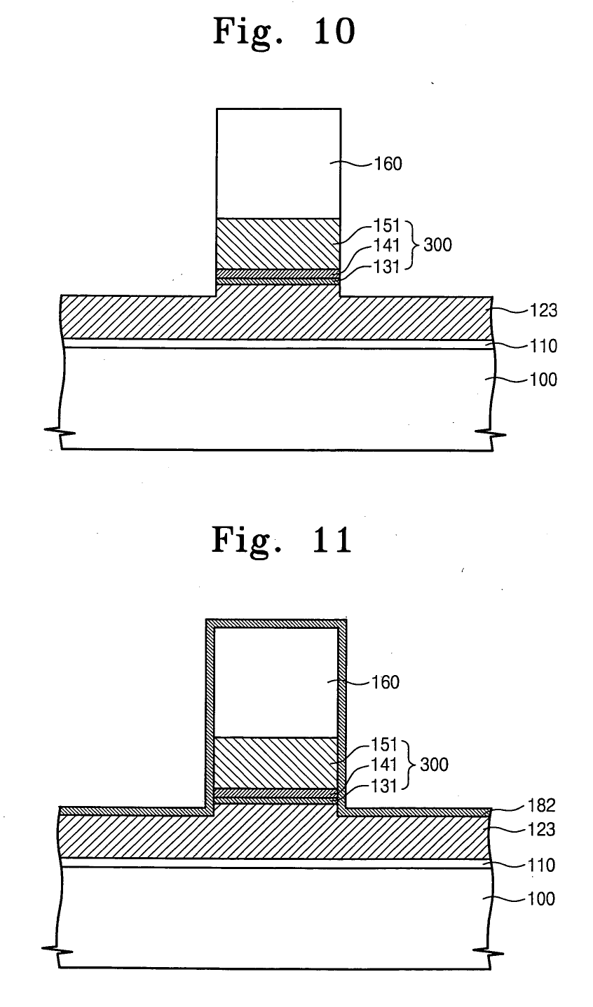

FIGS. 10 through 14 illustrate exemplary configurations and sequences of operations for a method of forming semiconductor devices according to still other embodiments of the present invention.

FIG. 10 illustrates a structure similar to that shown in FIG. 6. However, as shown in FIG. 10, an over-etch process is performed using the capping pattern 160 as an etch mask to form an upper part of the gate polysilicon layer 120 (FIG. 2). This results in forming a gate polysilicon layer 123 having a recessed region adjacent to the metal-containing pattern 300 and lower than a bottom surface of the metal silicide pattern 131.

Referring to FIG. 11, an oxidation barrier layer 182 can be substantially conformally formed over a target portion of an exposed/upper surface (typically an entire exposed surface) of the semiconductor substrate 100 having the gate polysilicon layer 123. Alternatively, the oxidation barrier layer 182 may be directly formed at an entire surface of the semiconductor substrate shown in FIG. 6, without performing the over-etch process. The oxidation barrier layer 182 can be formed, for example, by CVD or ALD. By controlling process conditions of the CVD and/or the ALD, the oxidation barrier layer 182 is conformally formed. The oxidation barrier layer 182 may comprise boron nitride, a metal, an oxide of the metal, a nitride of the metal or an oxynitride of the metal. The oxidation barrier layer 182 can be formed by using only a deposition process. The metal may comprise at least one selected from the group consisting of aluminum, tantalum, titanium hafnium, molybdenum, cobalt and gold. Alternatively, in order to form the oxidation barrier layer 182, a metal layer may be selectively deposed without any patterning process, then, oxidized or nitrified or successively oxidized and nitrified.

For example, where the oxidation barrier layer 182 is formed of a conformal aluminum oxide (Al₂O₃), a CVD chamber of chemically vapor-depositing the oxidation barrier layer 182 can be prepared. A temperature of the CVD chamber can beset to between about 200˜600° C. and a pressure of the CVD chamber can be set to between about 0.1˜10 Torr. Then, a gas mixture, such as source gases comprising ozone (O₃) and vapor of tri-methyl-aluminum (TMA) can be supplied. The gas mixture can include argon (Ar) that may be supplied as a carrier gas in to the CVD chamber. The TMA can be a liquid at a temperature of about 25° C. and a vapor pressure of the TMA can be about 15.6 Torr at 25° C. That is, for example, the vapor of the TMA which is vaporized from the liquid TMA at about 25° C. can be supplied into the CVD chamber by using the carrier gas, Ar. The ozone may be used in an amount of between about 50˜1000 g, more typically about 350 g per 1 m³ of the volume of the CVD chamber.

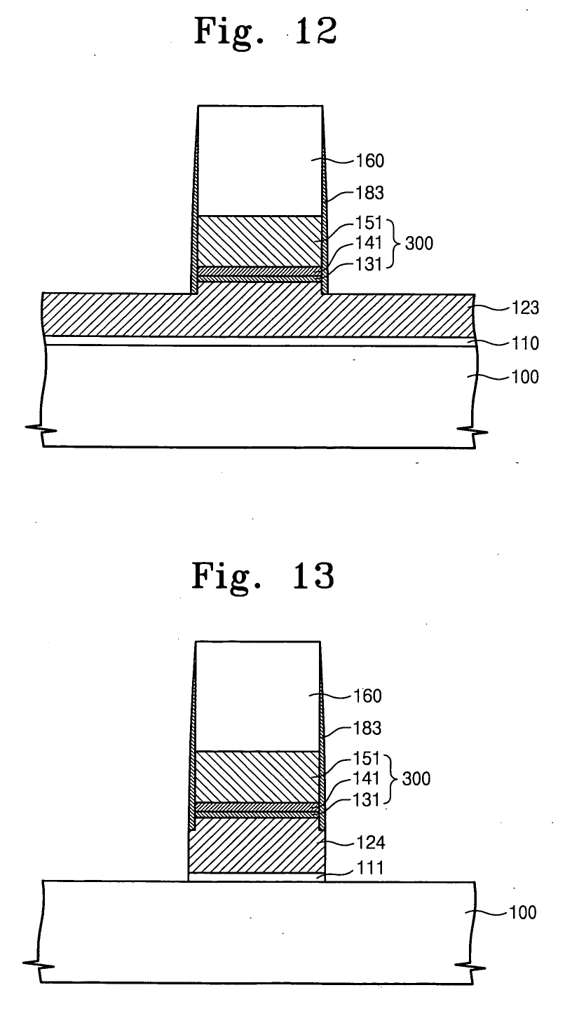

Referring to FIG. 12, an entire anisotropic etch process can be performed with respect to the conformal oxidation barrier layer 182, thereby removing the oxidation barrier layer 182 from the top and, optionally, part of the upper side surfaces of the capping pattern 160 and the gate polysilicon layer 123. The etch process can simultaneously form an oxidation barrier pattern 183 that covers at least a major portion of the length of the sidewalls of the capping pattern 160 (typically substantially the entire length of the capping pattern sidewalls under the top surface), the metal-containing pattern 300, and the upper sidewalls of the gate polysilicon layer 123. The upper sidewalls of layer 123 being the portion that is under and proximate the metal-containing pattern 300.

Referring to FIG. 13, the gate polysilicon layer 123 can be etched using the capping pattern 160 and the oxidation barrier pattern 183 as etch masks to form a gate polysilicon pattern 124. The gate polysilicon pattern 124 can have both a width that is larger than a width of the metal-containing pattern 300 and sidewalls with an outer profile that are aligned with (in-line with) sidewalls of the oxidation barrier pattern 183.

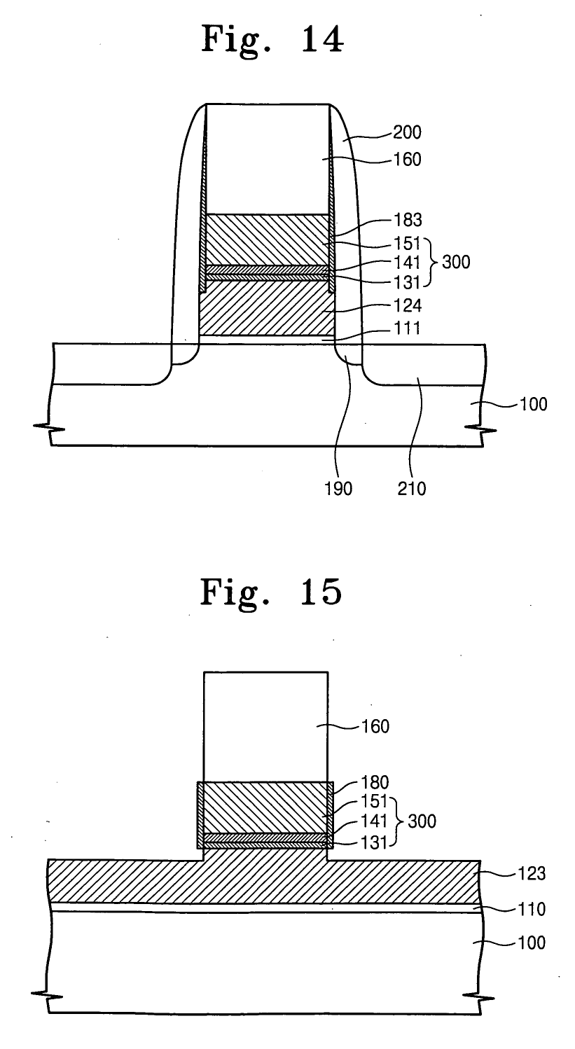

Referring to FIG. 14, a thermal treatment process can be performed under an oxygen-enriched environment to cure etch damages of the gate insulation pattern 111 and sidewalls of the gate polysilicon pattern 124. As shown, the oxidation barrier pattern 183 covers not only the sidewalls of the metal-containing pattern 300, but also sidewalls of the capping pattern 160 and upper portions of the sidewalls of the gate polysilicon pattern 124, so that oxygen can be inhibited/prevented from penetrating to inhibit the formation of an oxide layer. Impurities can be implanted into the semiconductor substrate 100 using the capping pattern 160 and the oxidation barrier pattern 183 as ion-implantation masks to form a low-concentration impurity-doped region 190. A spacer 200 can be formed to cover sidewalls of the capping pattern 160, the oxidation barrier pattern 183 and the gate polysilicon pattern 124. Impurities can be implanted into the semiconductor substrate 100 using the capping pattern 160 and the spacer 200 as ion-implantation masks to form a high-concentration impurity-doped region 210. In this embodiment, the layers and process conditions can be the same as those described above with respect to FIGS. 2 through 5.

Still referring to FIG. 14, the gate insulation pattern 111, the gate polysilicon pattern 124, the metal silicide pattern 131, the barrier metal pattern 141, the gate metal pattern 151 and the capping pattern 160 are sequentially stacked to define the gate pattern. As shown, sidewalls of the metal-containing pattern 300, the capping pattern 160 and sidewalls of the gate polysilicon pattern 124 are covered by the oxidation barrier pattern 183. As is also shown, an upper width of the oxidation barrier pattern 183 can be thinner than a bottom width thereof.

FIGS. 15 through 19 illustrate structures/operations that can be used to form semiconductor devices according to still other embodiments of the present invention.

Referring to FIG. 15, which illustrates a structure in the state of that shown in FIG. 10, a first oxidation barrier pattern 180 is selectively formed to cover substantially only the sidewalls of the metal-containing pattern 300, as explained above with respect to FIG. 4. That is, by using a difference of a chemical property, such as, for example, a nucleation rate, by controlling process conditions of CVD or ALD, the first oxidation barrier pattern 180 can be selectively formed on the sidewalls of the metal-containing pattern 300. The first oxidation barrier pattern 180 may comprise boron nitride, a metal, an oxide of the metal, a nitride of the metal or an oxynitride of the metal. The metal may comprise at least one selected from the group consisting of aluminum, tantalum, titanium hafnium, molybdenum, cobalt and gold.

Alternatively, in order to form the first oxidation barrier pattern 180, a metal pattern may be selectively deposited without any patterning process, and then, oxidized or nitrified or successively oxidized and nitrified.

In certain embodiments, such as, for example, when the first oxidation barrier pattern 180 is formed of aluminum oxide (Al₂O₃), an aluminum pattern may be formed substantially only on sidewalls of the metal-containing pattern 300 by supplying a gas mixture comprising, for example, methylpyrrolidine alane (MPA) as a source gas and argon (Ar) as a carrier gas. The gas mixture or carrier gas can be supplied at a flow rate of about 100 sccm. The gas mixture can be supplied at a temperature of between about 135˜145° C. and at a pressure of between about 0.1˜1.1 Torr. The gas mixture may be supplied for about 5 seconds using a CVD method. The aluminum pattern can be naturally oxidized (at pressures at about and/or under atmospheric pressure) to form the aluminum oxide of the oxidation barrier pattern 180. The aluminum pattern may be selectively deposited on surfaces of the metal-containing pattern 300 but substantially not on other surfaces, so that adjacent patterns 100, 111, 121 and 160 are substantially (and typically entirely) devoid of the oxide barrier pattern 180.

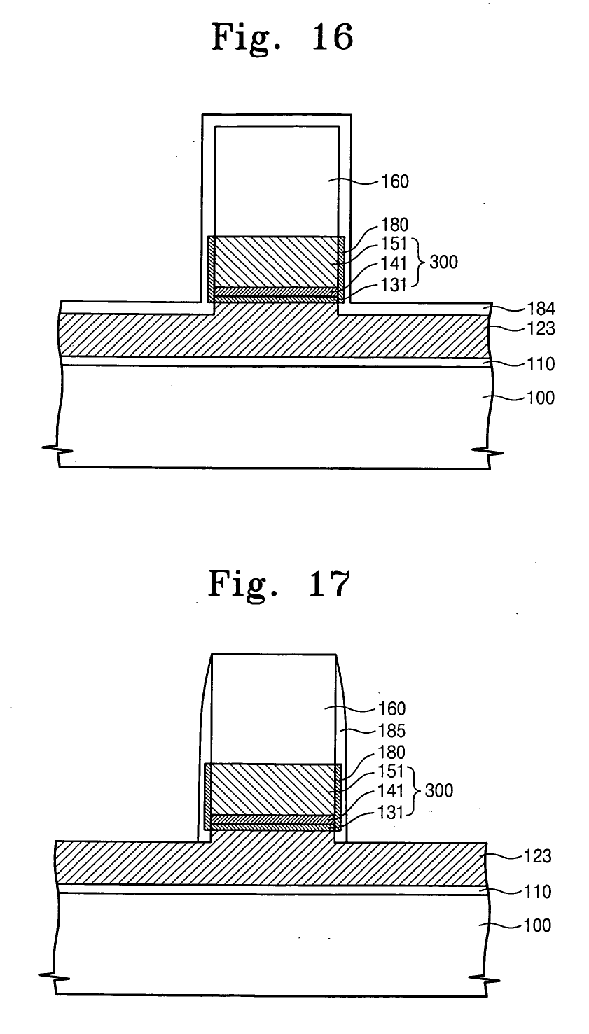

Referring to FIG. 16, a second oxidation barrier layer 184 is conformally formed over the entire exposed surfaces the semiconductor structure having the first oxidation barrier pattern 180. The oxidation barrier layer 184 can be formed by CVD or ALD. By controlling process conditions of the CVD and/or the ALD, the oxidation barrier layer 184 can be conformally formed. The oxidation barrier layer 184 can comprise silicon nitride. The oxidation barrier layer 184 may also comprise boron nitride, a metal, an oxide of the metal, a nitride of the metal or an oxynitride of the metal. The oxidation barrier layer 184 can be formed using only a deposition process. The metal may comprise at least one selected from the group consisting of aluminum, tantalum, titanium hafnium, molybdenum, cobalt and gold. Alternatively, in order to form the oxidation barrier layer 184, a metal layer may be selectively deposited without any patterning process, then, oxidized or nitrified or successively oxidized and nitrified.

For example, the oxidation barrier layer 184 may comprise a conformal aluminum oxide (Al₂O₃). More particularly, a CVD chamber of chemical vapor-deposition of the oxidation barrier layer 184 is prepared. A temperature of the CVD chamber is set to between about 200˜600° C. and a pressure of the CVD chamber can be set to between about 0.1˜10 Torr. Then, a gas mixture, such as, for example, a gas mixture comprising source gases, ozone (O₃) and vapor of tri-methyl-aluminum (TMA), and a carrier gas, such as argon (Ar), can be supplied into to the CVD chamber. The TMA is a liquid at a temperature of 25° C. and a vapor pressure of the TMA is about 15.6 Torr at 25° C. That is, for example, the vapor of the TMA, which is vaporized from the liquid TMA at 25° C., is supplied into the CVD chamber using the carrier gas, e.g., Ar. The ozone may be used in an amount of between 50˜1000 g, typically about 350 g per 1 m³ of the volume of the CVD chamber.

Referring to FIG. 17, an entire anisotropic etch process is performed with respect to the oxidation barrier layer 184 (FIG. 16), thereby removing the oxidation barrier layer 184 from an upper (top) surface of the capping pattern 160 and a recessed upper surface of the gate polysilicon layer 123 and simultaneously forming a second oxidation barrier pattern 185 covering sidewalls of the capping pattern 160 and the first oxidation barrier pattern 180 and the upper sidewalls of the gate polysilicon layer 123 (the portion of the gate polysilicon layer 123 under the layer 131).

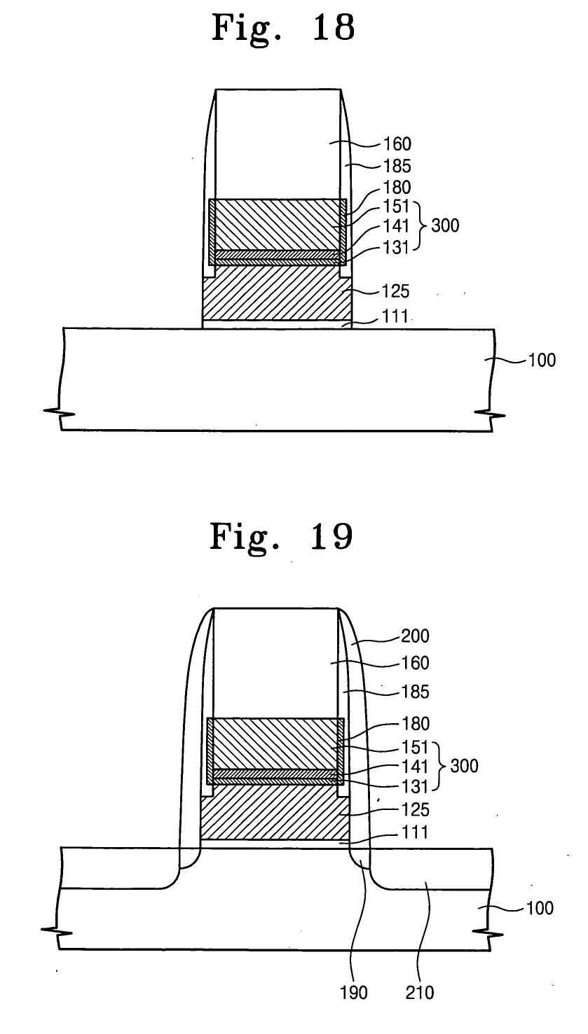

Referring to FIG. 18, the gate polysilicon layer 123 can be etched by using the capping pattern 160 and the second oxidation barrier pattern 185 as etch masks to from a gate polysilicon pattern 125. The gate polysilicon pattern 125 has both a width that is larger than a width of the metal-containing pattern 300 and sidewalls that are aligned with the sidewalls of the second oxidation barrier pattern 185 such that the respective outer perimeters are substantially collinear with each other.

Referring to FIG. 19, a thermal treatment process can be performed under an oxygen-enriched environment to cure etch-damages of the gate insulation pattern 111 and sidewalls of the gate polysilicon pattern 125. The first and second oxidation barrier patterns 180, 185, respectively, cover the sidewalls of the metal-containing pattern 300, so that oxygen can be inhibited from penetration into the gate metal pattern 151. Impurities can be implanted into the semiconductor substrate 100 using the capping pattern 160 and the second oxidation barrier pattern 185 as ion-implantation masks to form a low-concentration impurity-doped region 190. A spacer 200 can be formed to cover the outer sidewalls of the second oxidation barrier pattern 185 and the gate polysilicon pattern 125. Impurities can be implanted into the semiconductor substrate 100 using the capping pattern 160 and the spacer 200 as ion-implantation masks to form a high-concentration impurity-doped region 210.

Still referring to FIG. 19, the gate insulation pattern 111, the gate polysilicon pattern 125, the metal silicide pattern 131, the barrier metal pattern 141, the gate metal pattern 151 and a capping pattern 160 can be sequentially stacked to define a gate pattern. Sidewalls of the metal-containing pattern 300 are covered by the first oxidation barrier pattern 180. Outer sidewalls of the first oxidation barrier pattern 180 are covered by the second oxidation barrier pattern 185. The capping pattern 160 and upper portions of the sidewalls of the gate polysilicon pattern 125 are also covered by the second oxidation barrier pattern 185. An upper width of the second oxidation barrier pattern 185 is thinner than a bottom width thereof. The thickness of the second oxidation barrier pattern 185 can be thinner proximate the first oxidation barrier pattern 180 than at a lower and medial portion of the capping layer 160. As shown, the gate polysilicon pattern 125 has a width that is greater than a width of the metal-containing pattern 300.

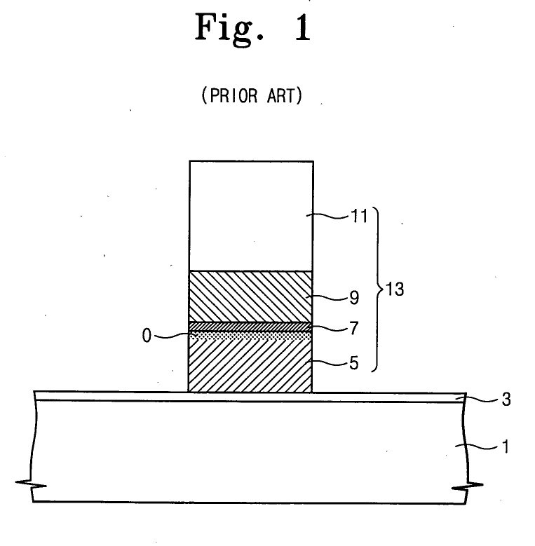

Accordingly, in methods of forming a semiconductor device and the device of the present invention, an oxidation barrier pattern is formed to cover sidewalls of the metal-containing pattern, and the metal-containing pattern located above a gate polysilicon layer includes a metal silicide pattern, metal barrier pattern and a gate metal pattern, which are sequentially stacked. An oxide layer (O, in FIG. 1) is inhibited from forming between the metal barrier pattern and the gate polysilicon pattern. Furthermore, a metal silicide pattern located between the metal barrier pattern and the gate polysilicon pattern can function as an ohmic layer, decreasing a contact resistance between the metal barrier pattern and the gate polysilicon pattern, and as an oxidation barrier to inhibit (typically prevent) a metal such as tungsten from being oxidized. Therefore, embodiments of the instant invention can improve operational speed and reliability of semiconductor devices. The gate pattern may include a plurality of opposing sidewalls where the shape of the gate pattern (when viewed from the top) is rectangular, square or other shape with more than one sidewall. However, the gate pattern can include cylindrical, circular, or other shapes with only one sidewall as well as other multi-sided configurations. Hence, in the claims, the term “sidewall(s)” is intended to encompass these sidewall configurations. In addition, although a respective one gate pattern is illustrated in the figures, a highly integrated device can comprise a plurality of the gate patterns, repeated on the substrate, as will be understood by one of skill in the art.

Accordingly, methods of forming semiconductor devices according to embodiments of the present invention can form an oxidation barrier layer covering at least a portion of the sidewall of the metal gate pattern layer, thereby inhibiting and/or preventing formation of an oxide layer between the metal gate pattern and the gate polysilicon pattern which may occur due to oxygen penetration in a subsequent process.

What is claimed is:

1. A method of forming a semiconductor device comprising:
sequentially forming a gate insulation layer, a gate polysilicon layer and a plurality of metal-containing layers on a semiconductor substrate;
patterning the plurality of metal-containing layers to form a metal-containing pattern; and
forming an oxidation barrier pattern covering sidewalls of the metal-containing pattern,
wherein the plurality of metal-containing layers includes at least three layers formed by sequentially stacking a metal silicide layer, a barrier metal layer and a gate metal layer to define the stacked metal-containing pattern that comprises, in serial order, a metal silicide pattern, a barrier metal pattern and a gate metal pattern.

2. The method of claim 1, wherein the forming of a metal-containing pattern comprises:
forming a capping pattern on an upper surface of the metal-containing layer; then
patterning the plurality of metal-containing layers using the capping pattern as an etch mask.

3. The method of claim 2, wherein the forming the gate polysilicon layer comprises etching the gate polysilicon layer using the capping pattern as an etch mask to form a gate polysilicon pattern having sidewalls aligned with sidewalls of the metal-containing pattern,
wherein the oxidation barrier pattern is formed to cover substantially only the sidewalls of the metal-containing pattern.

4. The method of claim 2, wherein the forming the oxidation barrier pattern comprises selectively forming an oxidation barrier pattern covering substantially only the sidewalls of the metal-containing pattern by performing at least one of a chemical vapor deposition or an atomic layer deposition.

5. The method of claim 2, wherein the oxidation barrier pattern comprises at least one of boron nitride, a metal, an oxide of the metal, a nitride of the metal or an oxynitride.

6. The method of claim 5, wherein the oxidation pattern comprises at least one metal selected from the group consisting of aluminum, tantalum, titanium, hafnium, molybdenum, cobalt and gold.

7. The method of claim 2, wherein forming the oxidation barrier pattern comprises:
forming a metal pattern that selectively covers substantially only the sidewalls of the metal-containing pattern by a chemical vapor deposition or an atomic layer deposition; and
oxidizing or nitrifying or successively oxidizing and nitrifying the metal pattern.

8. The method of claim 2, wherein the oxidation barrier pattern comprises aluminum oxide (Al₂O₃), and the forming of the oxidation barrier pattern comprises:
forming an aluminum pattern covering substantially only the sidewalls of the metal-containing pattern by using a chemical vapor deposition and by supplying a gas mixture comprising methylpyrrolidine alane (MPA) gas and argon (Ar) gas at a temperature of between about 135˜145° C. and at a pressure of between about 0.1˜1.1 Torr; and
oxidizing the aluminum pattern in an oxygen-enriched environment.

9. The method of claim 2, wherein the oxidation barrier pattern is formed to cover substantially only the sidewalls of the metal-containing pattern,
the method further comprising, after forming the oxidation barrier pattern, etching the gate polysilicon layer using the capping pattern and the oxidation barrier pattern as etch masks to form a gate polysilicon pattern having sidewalls aligned with sidewalls of the oxidation barrier pattern.

10. The method of claim 2, wherein the oxidation barrier pattern covers the sidewalls of the metal-containing pattern and at least portions of sidewalls of the capping pattern,
the method further comprising, after forming the oxidation barrier pattern, etching the gate polysilicon layer using the capping pattern and the oxidation barrier pattern as etch masks to form a gate polysilicon pattern having sidewalls aligned with sidewalls of the oxidation barrier pattern.

11. The method of claim 10, wherein forming the oxidation barrier pattern comprises:
conformally forming an oxidation barrier layer over exposed surfaces of the gate polysilicon layer, the metal-containing pattern and the capping pattern; then
anisotropically etching the oxidation barrier layer to remove the oxidation barrier layer on an upper surface of the capping pattern and the gate polysilicon layer and simultaneously forming the oxidation barrier pattern covering the sidewalls of the metal-containing pattern and sidewalls of the capping pattern.

12. The method of claim 11, wherein the oxidation barrier pattern comprises at least one of boron nitride, a metal, an oxide of the metal, a nitride of the metal or an oxynitride.

13. The method of claim 12, wherein the oxidation barrier pattern comprises at least one metal selected from the group consisting of aluminum, tantalum, titanium, hafnium, molybdenum, cobalt and gold.

14. The method of claim 11, wherein forming the oxidation barrier layer comprises:
selectively forming a metal layer over exposed surfaces of the semiconductor device having the metal-containing pattern; and
oxidizing or nitrifying or successively oxidizing and nitrifying the metal layer.

15. The method of claim 11, wherein the oxidation barrier layer comprises aluminum oxide (Al₂O₃), and wherein forming the oxidation barrier layer comprises using a chemical vapor deposition and a gas mixture comprising vapor of tri-methyl-aluminum (TMA), ozone (O₃) gas argon (Ar) gas at a temperature of between about 200˜600° C. and at a pressure of between about 0.1˜10 Torr.

16. The method of claim 1, further comprising forming a capping pattern on an upper surface of an uppermost one of the metal-containing layers,
wherein the oxidation barrier pattern comprises a first oxidation barrier pattern covering substantially only sidewalls of the metal-containing pattern and a second oxidation barrier pattern covering sidewalls of the first oxidation barrier pattern and at least a portion of sidewalls of the capping pattern,
the method further comprising, after forming the second oxidation barrier pattern, etching the gate polysilicon layer using the capping pattern and the second oxidation barrier pattern as etch masks to form a gate polysilicon pattern having sidewalls aligned with sidewalls of the second oxidation barrier pattern.

17. The method of claim 16, wherein forming of the oxidation barrier pattern comprises:
selectively forming a first oxidation barrier pattern covering substantially only the sidewalls of the metal-containing pattern using at least one of chemical vapor deposition or atomic layer deposition; then
conformally forming a second oxidation barrier layer over the exposed surfaces of the capping pattern and the gate polysilicon layer of a semiconductor substrate holding the stacked metal-containing pattern; and
performing an anisotropic etch process with respect to the second oxidation barrier layer to remove the second oxidation barrier layer from upper surfaces of the capping pattern and the gate polysilicon layer to form the second oxidation barrier pattern that covers sidewalls of the first oxidation barrier pattern and the capping pattern.

18. The method of claim 17, wherein the first and second oxidation barrier patterns comprise at least one of boron nitride, a metal, an oxide of the metal, a nitride of the metal or an oxynitride.

19. The method of claim 18, wherein the first and second oxidation barrier patterns include at least one metal selected from the group consisting of aluminum, tantalum, titanium, hafnium, molybdenum, cobalt and gold.

20. The method of claim 17, wherein the second oxidation barrier pattern comprises silicon nitride.

21. The method of claim 17, wherein the forming of the first oxidation barrier comprises:
selectively forming a metal pattern covering substantially only sidewalls of the metal-containing pattern by using a chemical vapor deposition or an atomic layer deposition; and
oxidizing or nitrifying and/or successively oxidizing and nitrifying the metal pattern.

22. The method of claim 17, wherein the forming of the second oxidation barrier layer comprises:
forming a metal layer over exposed surfaces of the polysilicone layer, sidewalls of the first oxidation barrier pattern, and the capping pattern; and
oxidizing or nitrifying or successively oxidizing and nitrifying the metal layer.

23. The method of claim 17, wherein the first oxidation barrier pattern comprises aluminum oxide (Al₂O₃), and the forming of the first oxidation barrier pattern comprises:
forming an aluminum pattern covering substantially only the sidewalls of the metal-containing pattern using a chemical vapor deposition and a gas mixture comprising methylpyrrolidine alane (MPA) and argon (Ar) gases at a temperature of between about 135˜145° C. and at a pressure of between about 0.1˜1.1 Torr; and
oxidizing the aluminum pattern in an oxygen-enriched environment.

24. The method as claimed in claim 17, wherein the second oxidation barrier layer comprises aluminum oxide (Al₂O₃), and the forming of the second oxidation barrier layer is carried out using a chemical vapor deposition and a gas mixture comprising vapor of tri-methyl-aluminum (TMA), ozone (O₃) gas and argon (Ar) gas at a temperature of between about 200˜600° C. and at a pressure of between about 0.1˜10 Torr.

25. The method as claimed in claim 1, further comprising forming a gate polysilicon pattern from the gate polysilicon layer after forming the oxidation barrier pattern, then thermally treating, the semiconductor device with the oxidation barrier pattern and the gate polysilicon pattern in an oxygen-enriched environment.

26. The method as claimed in claim 25, wherein the thermally treating comprises supplying a gas mixture comprising nitrogen, oxygen and hydrogen at a temperature of between about 750˜950° C. and a ratio of oxygen/hydrogen of between about 0.5˜1.3.

27. A semiconductor device comprising:
a gate insulation pattern on a semiconductor substrate;
a gate polysilicon pattern on the gate insulation pattern;
a metal-containing pattern on the gate polysilicon pattern;
a capping pattern on the metal-containing pattern; and
an oxidation barrier pattern covering sidewalls of the metal-containing pattern,
wherein the metal-containing pattern comprises a serially stacked configuration of a metal silicide pattern, a metal barrier pattern and a gate metal pattern.

28. The device of claim 27, wherein the gate polysilicon pattern has sidewalls with an outer perimeter profile that is aligned with an outer perimeter profile of sidewalls of the metal-containing pattern, and wherein the oxidation barrier pattern covers substantially only the sidewalls of the metal-containing pattern.

29. The device of claim 27, wherein the gate polysilicon pattern has sidewalls that are aligned with sidewalls of the oxidation barrier pattern.

30. The device of claim 29, wherein the oxidation barrier pattern covers substantially only the sidewalls of the metal-containing pattern.

31. The device of claim 29, wherein the oxidation barrier pattern covers at least a portion of sidewalls of the capping pattern and sidewalls of the metal-containing pattern.

32. The device of claim 27, wherein the oxidation barrier pattern comprises at least one of the following: boron nitride, a metal, an oxide of the metal, a nitride of the metal, or an oxynitride of the metal.

33. The device of claim 32, wherein the oxidation barrier pattern comprises at least one metal selected from the group consisting of aluminum, tantalum, titanium, hafnium, molybdenum, cobalt and gold.

34. The device of claim 29, wherein the oxidation barrier pattern comprises a first oxidation barrier pattern covering substantially only sidewalls of the metal-containing pattern, and a second oxidation barrier pattern covering sidewalls of the first oxidation barrier pattern and at least a major portion of sidewalls of the capping pattern.

35. The device of claim 34, wherein the first and second oxidation barrier patterns comprise at least one of the following: boron nitride, a metal, an oxide of the metal, a nitride of the metal, or an oxynitride of the metal.

36. The device of claim 35, wherein the oxidation barrier pattern comprises at least one metal selected from the group consisting of aluminum, tantalum, titanium, hafnium, molybdenum, cobalt and gold.

37. The device of claim 34, wherein the second oxidation barrier pattern comprises silicon nitride.

38. A highly integrated semiconductor device, comprising:
a semiconductor substrate;
a plurality of spaced apart gate structures disposed on the semiconductor substrate, each gate structure comprising, in serial order:
a polysilicon gate pattern;
a multi-layer metal-containing stacked pattern residing on the polysilicon gate pattern, the multi-layer metal-containing stacked pattern including a first metal silicide pattern residing on the polysilicon gate pattern, a second metal barrier pattern residing above the polysilicon gate pattern on the first metal silicide pattern, and a third gate metal pattern residing on the second metal barrier pattern above the first metal silicide pattern;
a capping pattern residing on the third gate metal pattern of the multi-layer metal-containing pattern; and
at least one oxygen barrier pattern covering sidewalls of the metal-containing pattern, whereby after exposure to an oxygen enriched environment, the gate structures are devoid of an oxide layer intermediate the metal barrier pattern and the gate polysilicone pattern.

39. A semiconductor device according to claim 38, wherein the metal silicide pattern defines an ohmic layer with low contact resistance between the metal barrier pattern and the gate polysilicon pattern and defines an oxygen barrier to inhibit metal in the metal barrier pattern and/or the third gate metal pattern from being oxidized.

40. A method of forming a semiconductor device comprising:
sequentially forming a gate insulation layer, a gate polysilicon layer and a plurality of metal-containing layers on a semiconductor substrate, wherein the metal-containing layers are formed by sequentially forming a first metal-containing layer on the gate polysilicon layer, then forming a second metal-containing barrier layer on the first metal-containing layer, then forming a third metal-containing gate layer on the second metal-containing barrier layer, wherein at least one of the metal-containing layers has a different material composition from the others;
patterning the metal-containing layers to form a stacked metal-containing pattern; then
forming an oxidation barrier pattern covering sidewalls of the metal-containing pattern.
